(19) United States
(12) Patent Application Publication
(10) Pub. No.: US 2023/0105522 A1
(43) Pub. Date: Apr. 6, 2023

(54) REMOVING APPARATUS

(71) Applicant: Tokyo Electron Limited, Tokyo (JP)

(72) Inventors: Takahiro SAKAMOTO, Koshi-shi, Kumamoto (JP); Munehisa KODAMA, Kikuchi-gun, Kumamoto (JP)

(21) Appl. No.: 17/907,102

(22) PCT Filed: Mar. 2, 2021
(86) PCT No.: PCT/JP2021/007824

§ 371 Date: Sep. 23, 2022

(30) Foreign Application Priority Data
Mar. 24, 2020 (JP) 2020-052488
Sep. 25, 2020 (JP) 2020-161269

(51) Int. Cl. B24B 7/04; B24B 41/06

(52) U.S. Cl. CPC B24B 7/04; B24B 41/06

(57) ABSTRACT

A removing apparatus includes a table, multiple chucks, a nozzle and a table cover. The table is horizontally provided and configured to be rotated around a vertical rotation center line. The multiple chucks are disposed at a distance therebetween around the rotation center line of the table. The nozzle is configured to supply a processing liquid to a substrate held by the chuck. The table cover is configured to receive the processing liquid from above the table. The table cover has an inclined member of a conical shape having a decreasing height as the inclined member goes away from the rotation center line of the table while having a constant height in a rotation direction.

### TECHNICAL FIELD

The various aspects and embodiments described herein pertain generally to a removing apparatus.

### BACKGROUND

A processing apparatus described in Patent Document 1 is equipped with a first transfer unit, a position adjusting mechanism, a second transfer unit, a turntable, a chuck table, a processing unit, and a cleaning mechanism. The first transfer unit transfers a substrate from a cassette to the position adjusting mechanism. The position adjusting mechanism adjusts the position of the substrate. The second transfer unit transfers the substrate from the position adjusting mechanism to the chuck table on the turntable. If the chuck table attracts and holds the substrate, the turntable is spun to place the substrate below the processing unit. The processing unit grinds the substrate with a grinding wheel. The second transfer unit is turned while attracting and holding the substrate after being ground, and transfers the substrate to the cleaning mechanism. The cleaning mechanism cleans the substrate after being ground. The first transfer unit transfers the cleaned substrate from the cleaning mechanism to the cassette.

### PRIOR ART DOCUMENT

Patent Document 1: Japanese Patent Laid-open Publication No. 2019-185645

### DISCLOSURE OF THE INVENTION

### Problems to be Solved by the Invention

Exemplary embodiments provide a technique enabling to suppress deposition of processing residues on a cover by suppressing a processing liquid including the processing residues from being left on the cover.

### Means for Solving the Problems

In an exemplary embodiment, a removing apparatus includes a table, multiple chucks, a nozzle and a table cover. The table is horizontally provided and configured to be rotated around a vertical rotation center line. The multiple chucks are disposed at a distance therebetween around the rotation center line of the table. The nozzle is configured to supply a processing liquid to a substrate held by the chuck. The table cover is configured to receive the processing liquid from above the table. The table cover has an inclined member of a conical shape having a decreasing height as the inclined member goes away from the rotation center line of the table while having a constant height in a rotation direction of the table.

### Effect of the Invention

According to the exemplary embodiments, it is possible to suppress the processing liquid including the processing residues from being left on the cover, thus making it possible to suppress the processing residues from being deposited on the cover.

### BRIEF DESCRIPTION OF THE DRAWINGS

FIG. 1 is a plan view of a grinding apparatus according to an exemplary embodiment.

FIG. 2 is a cross sectional view illustrating an example of a grinding unit.

FIG. 3 is a perspective view illustrating an example of a grinding position cover.

FIG. 4 is a cross sectional view illustrating an example of a table cover, a chuck cover and a base cover.

FIG. 5 is a cross sectional view illustrating a modification example of the table cover, the chuck cover, and the base cover.

FIG. 6 is a cross sectional view illustrating a second modification example of the chuck cover, the table cover, and the base cover.

FIG. 7A is a top view illustrating an example of an inner cylindrical member shown in FIG. 6, and FIG. 7B is a top view illustrating a state in which a part of the inner cylindrical member of FIG. 7A is separated.

FIG. 8 is a cross sectional view illustrating an example of a state in which a part of the inner cylindrical member shown in FIG. 6 is separated.

FIG. 9 is a plan view illustrating an example flow of a cleaning liquid.

### DETAILED DESCRIPTION

Hereinafter, exemplary embodiments of the present disclosure will be described with reference to the accompanying drawings. Further, in the various drawings, same or corresponding parts will be assigned same reference numerals, and redundant description will sometimes be omitted. In the present specification, the X-axis direction, the Y-axis direction and the Z-axis direction are orthogonal to each other. The X-axis and Y-axis directions are horizontal directions, and the Z-axis direction is a vertical direction.

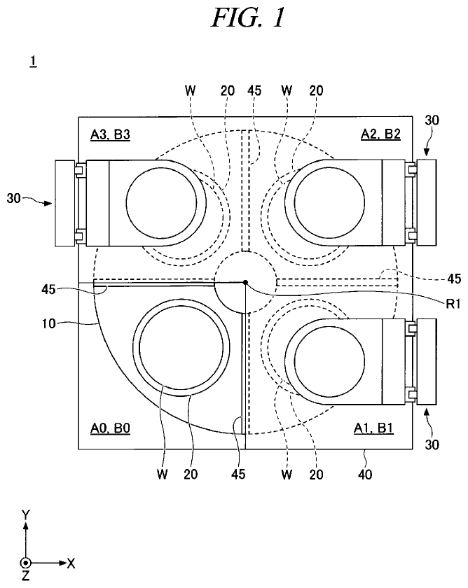

First, referring to FIG. 1, a grinding apparatus 1 will be described. The grinding apparatus 1 is configured to grind a substrate W. The substrate W includes a semiconductor substrate such as a silicon wafer or a compound semiconductor wafer, or a glass substrate. The substrate W may further include a device layer formed on a surface of the semiconductor substrate or the glass substrate. The device layer includes an electronic circuit. Further, the substrate W may be a combined substrate in which multiple substrates are bonded. Grinding includes polishing. Abrasive grains for use in the grinding may be fixed abrasive grains or free abrasive grains. The grinding apparatus 1 includes, for example, a table 10, four chucks 20, and three grinding units 30.

The table 10 holds the four chucks 20 at an equal distance therebetween around a rotation center line R1, and is configured to be rotated around the rotation center line R1. When viewed from above, the rotation direction of the table 10 is switched between a clockwise direction and a counterclockwise direction. Each of the four chucks 20 is rotated along with the table 10 and moved to a carry-in/out position A0, a first grinding position A1, a second grinding position A2, a third grinding position A3, and back to the carry-in/out position A0 in this order.

The carry-in/out position A0 is a position where a carry-in/out of the substrate W to/from the chuck 20 is performed, and serves as both a carry-in position where the substrate W is carried in and a carry-out position where the substrate W is carried out. Further, in the present exemplary embodiment, although the carry-in position and the carry-out position are same, they may be different. The first grinding position A1 is a position where first grinding of the substrate W is performed. The second grinding position A2 is a position where second grinding of the substrate W is performed. The third grinding position A3 is a position where third grinding of the substrate W is performed.

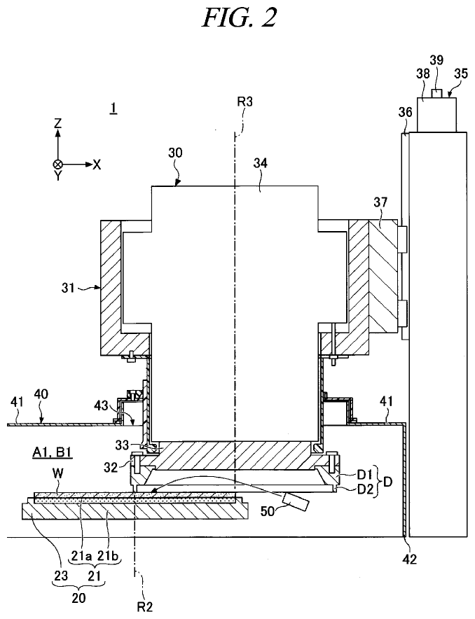

The four chucks 20 are mounted to the table 10 so as to be rotatable about their own rotation center lines R2 (see FIG. 2). At the first grinding position A1, the second grinding position A2, and the third grinding position A3, the chucks 20 are rotated about their own rotation center lines R2.

One of the grinding units 30 performs the first grinding of the substrate W at the first grinding position A1. Another grinding unit 30 performs the second grinding of the substrate W at the second grinding position A2. The other grinding unit 30 performs the third grinding of the substrate W at the third grinding position A3.

The grinding unit 30 is a tool driving unit that drives a grinding tool D. The tool driving unit 30 rotates the grinding tool D or moves it up and down. Here, the number of the grinding units 30 may be one or more. In addition, the number of the chucks 20 needs to be larger than the number of the grinding units 30.

Now, referring to FIG. 2, the grinding unit 30 will be explained. The grinding unit 30 includes a movable unit 31 to which the grinding tool D is mounted. The grinding tool D is brought into contact with the substrate W to grind it. The grinding tool D includes, for example, a disk-shaped grinding wheel D1 and a plurality of whetstones D2 arranged in a ring shape on a bottom surface of the grinding wheel D1.

The movable unit 31 includes a flange 32 to which the grinding tool D is mounted, a spindle shaft 33 having the flange 32 at a lower end thereof, and a spindle motor 34 configured to rotate the spindle shaft 33. The flange 32 is disposed horizontally, and the grinding tool D is mounted on a bottom surface thereof. The spindle shaft 33 is vertically disposed. The spindle motor 34 is configured to rotate the spindle shaft 33, thus allowing the grinding tool D mounted to the flange 32 to be rotated. A rotation center line R3 of the grinding tool D coincides with a rotation center line of the spindle shaft 33.

The grinding unit 30 further includes an elevating unit 35 configured to move the movable unit 31 up and down. The elevating unit 35 includes, for example, a vertical Z-axis guide 36, a Z-axis slider 37 configured to be moved along the Z-axis guide 36, and a Z-axis motor 38 configured to move the Z-axis slider 37. The movable unit 31 is fixed to the Z-axis slider 37, and the movable unit 31 and the grinding tool D are moved up and down along with the Z-axis slider 37. The elevating unit 35 is further equipped with a position detector 39 configured to detect a position of the grinding tool D. By way of example, the position detector 39 detects a rotation of the Z-axis motor 38 to detect the position of the grinding tool D.

The elevating unit 35 lowers the grinding tool D from a standby position. The grinding tool D is rotated while being lowered, comes into contact with a top surface of the substrate W being rotated, and grinds the entire top surface of the substrate W. When the thickness of the substrate W reaches a set value, the elevating unit 35 stops the descent of the grinding tool D. Thereafter, the elevating unit 35 raises the grinding tool D up to the standby position.

As shown in FIG. 2, the grinding apparatus 1 has a grinding position cover 40 and a nozzle 50. The grinding position cover 40 is a housing. For example, the grinding position cover 40 covers the first grinding position A1, the second grinding position A2, and the third grinding position A3 from above and from the side. Further, the grinding position cover 40 accommodates the chuck 20, the grinding tool D, and the nozzle 50 inside. The nozzle 50 is configured to supply a grinding liquid to the substrate W held by the chuck 20.

The grinding position cover 40 suppresses the grinding liquid and particles such as grinding residues from being scattered to the outside thereof. The grinding position cover 40 has a top panel 41 disposed horizontally and a side panel 42 disposed vertically. An insertion opening 43 for the movable unit 31 is formed in the top panel 41. The grinding position cover 40 has therein a grinding chamber in which the grinding of the substrate W is performed. A non-illustrated collecting pan is installed under the grinding position cover 40. The collecting pan collects the particles and the grinding liquid.

The nozzle 50 supplies the grinding liquid. The grinding liquid is, for example, pure water such as DIW (Deionized Water). The grinding liquid enters a gap between the substrate W and the grinding tool D, and reduces grinding resistance to suppress heat generation.

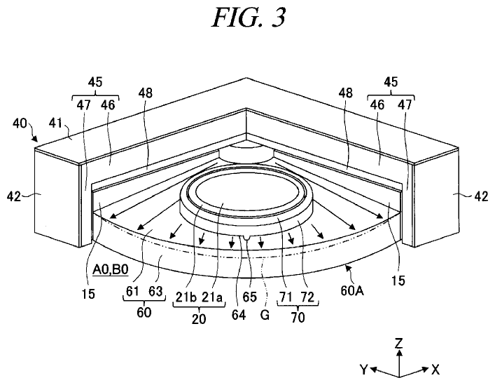

As illustrated in FIG. 3, the grinding position cover 40 includes a fixed partition wall 45. The fixed partition wall 45 is provided on a bottom surface of the top panel 41. The fixed partition wall 45 is plural in number, and the plurality of fixed partition walls 45 are arranged at an equal distance therebetween around the rotation center line R1 of the table 10 to separate the carry-in/out position A0, the first grinding position A1, the second grinding position A2, and the third grinding position A3. The fixed partition wall 45 is fixed to a bottom surface of the top panel 41. When viewed from above, the fixed partition wall 45 is extended in a diametrical direction (a direction orthogonal to the rotation center line R1) of the table 10.

As depicted in FIG. 1, the fixed partition walls 45 are arranged in, for example, a cross shape, and divide the inside of the housing 40 into four rooms B0 to B3 around the rotation center line R1 of the table 10. The three rooms B1 to B3 serve grinding chambers in which the grinding of the substrate W is performed. The room B1 is a first grinding chamber; B2, a second grinding chamber; and B3, a third grinding chamber. The remaining one room B0 is a carry-in/out chamber in which the carry-in/out of the substrate W is performed. The carry-in/out of the substrate W includes transferring the substrate W by an external transfer device and the chuck 20. The carry-in/out chamber B0 is opened upwards.

When viewed from above, the inside of the housing 40 is partitioned into the carry-in/out chamber B0, the first grinding chamber B1, the second grinding chamber B2, and the third grinding chamber B3 in this order in a counterclockwise direction. Here, the order of the four rooms B0 to B3 may be reversed, so when viewed from above, the inside of the housing 40 may be partitioned into the carry-in/out chamber B0, the first grinding chamber B1, the second grinding chamber B2, and the third grinding chamber B3 in this order in a clockwise direction. Furthermore, the number of the rooms is not limited to the four as long as it is more than one.

As illustrated in FIG. 3, the fixed partition wall 45 includes, for example, a top member 46 and a side member 47. The top member 46 is provided on the bottom surface of the top panel 41 and forms a gap with respect to the table 10. This gap allows the chuck 20 and the substrate W to pass therethrough when the table 10 is rotated. Provided on a lower edge of the top member 46 is a flexible sheet 48 of a rectangular shape that closes a gap between the top member 46 and the substrate W. The side member 47 is provided on an inner wall surface of the side panel 42. The side member 47 is protruded downwards from the top member 46 and closes a gap between a side surface of the table 10 and the side panel 42.

Rotary partition walls 15 are provided on a top surface of the table 10, and they are rotated along with the table 10. The number of the rotary partition walls 15 is the same as the number of the fixed partition walls 45. When the rotation of the table 10 is stopped, the rotary partition walls 15 are located directly under the fixed partition walls 45. Due to the presence of the fixed partition walls 45 and the rotary partition walls 15, it is possible to suppress the particles generated in the grinding chamber from being flown out to the outside of the grinding chamber. By way of example, introduction of grinding residues from the first grinding chamber B1 and the third grinding chamber B3 into the carry-in/out chamber B0 is suppressed, so that the carry-in/out chamber B0 can be maintained clean. Moreover, introduction of first grinding residues having a large particle diameter from the first grinding chamber B1 into the second grinding chamber B2 is suppressed, so that roughening of a ground surface of the substrate W after being subjected to the second grinding is suppressed. In addition, since introduction of second grinding residues having a large particle diameter from the second grinding chamber B2 into the third grinding chamber B3 is suppressed, the ground surface after being subjected to the third grinding is suppressed from being roughened.

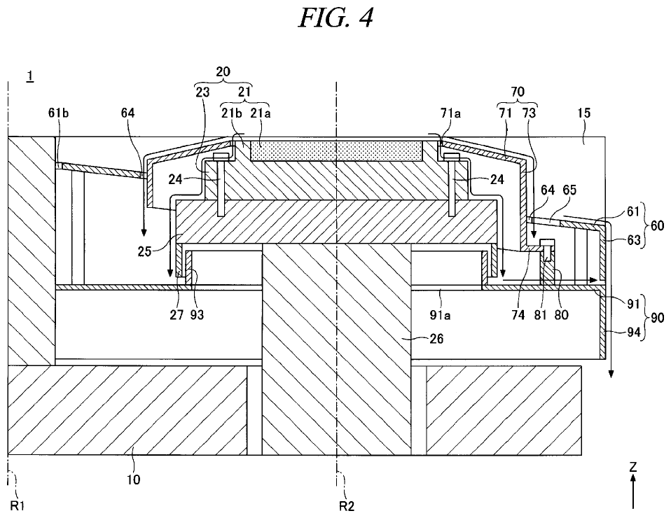

As shown in FIG. 4, the grinding apparatus 1 has a table cover 60. The table cover 60 receives the grinding liquid from above the table 10. The table cover 60 is fixed to the table 10 and rotated along with the table 10.

The table cover 60 has an inclined member 61. The inclined member 61 has a conical shape having a decreasing height as it goes away form the rotation center line R1 of the table 10 while having a constant height in a rotation direction of the table 10. This conical inclined member 61 may have an opening 61b at the top thereof.

Unlike a horizontal flat member, the conical inclined member 61 can drain the grinding liquid obliquely downwards by gravity. Therefore, the grinding liquid can be suppressed from being left on the table cover 60, so that deposition of the grinding residues contained in the grinding liquid can be suppressed.

Further, unlike an inclined member having a pyramid shape such as a quadrangular pyramid shape, the conical inclined member 61 can drain the grinding liquid radially as indicated by arrows in FIG. 3. Therefore, the grinding liquid can be drained while being uniformly distributed in the rotation direction of the table 10.

When the table cover 60 has the quadrangular pyramid-shaped inclined member instead of the conical inclined member 61, a groove G indicated by a dashed double-dotted line in FIG. 3 is formed. Since the chuck 20 is located at the bottom of the groove G, the grinding liquid tends to be easily accumulated near the chuck 20, and the grinding residues may be easily deposited thereat.

According to the present exemplary embodiment, the table cover 60 has the conical inclined member 61. Therefore, as described above, the grinding liquid can be drained radially as indicated by the arrows in FIG. 3, so that it is possible to suppress the grinding residues from being deposited near the chuck 20.

Since the deposition of the grinding residues can be suppressed, contamination of the grinding apparatus 1 can be reduced. Therefore, contamination caused by an operator or a work robot may be suppressed when maintenance, such as replacement of the grinding tool D or replacement of the chuck 20, is performed. Furthermore, it is also possible to suppress the deposited grinding residues from being peeled off and adhering to the chuck 20 or the substrate W.

As illustrated in FIG. 4, the table cover 60 has a straight member 63 extending downwards from a lower edge of the inclined member 61. Although the straight member 63 is extended straightly downwards from the lower edge of the inclined member 61 in the present exemplary embodiment, it may be extended diagonally downwards. The straight member 63 has a cylindrical shape centering on the rotation center line R1 of the table 10. The straight member 63 guides the grinding liquid dripping from the inclined member 61 downwards. The straight member 63 is disposed farther from the rotation center line R1 of the table 10 than the table 10, allowing the grinding liquid to fall outside the table 10.

The table cover 60 is divided into a plurality (only one is shown in FIG. 3) of division covers 60A between the chucks 20 neighboring in the rotation direction of the table 10. The number of the division covers 60A is the same as the number of the chucks 20. The rotary partition walls 15 are disposed between the division covers 60A neighboring in the rotation direction of the table 10.

The plurality of division covers 60A are individually provided to the table 10 in a removable manner. For maintenance, each division cover 60A can be separated individually. Since it is not necessary to remove the whole table cover 60 at once, workability can be improved.

As shown in FIG. 4, the grinding apparatus 1 has a chuck cover 70. The chuck cover 70 is protruded upwards from the inclined member 61 of the table cover 60, and receives the grinding liquid from around the chuck 20.

The chuck cover 70 is provided for each chuck 20. The chuck cover 70 also serves to suppress an object from being drawn into the chuck 20 when the chuck 20 is rotated. The chuck cover 70 is fixed to the table 10 and rotated along with the table 10.

The chuck cover 70 has an annular member 71. The annular member 71 has a conical shape having a decreasing height as it goes farther form a rotation center line R2 of the chuck 20 while having a constant height in a rotation direction of the chuck 20.

Unlike a horizontal flat member, the conical annular member 71 can drain the grinding liquid obliquely downwards by gravity. Therefore, the grinding liquid can be suppressed from being left on the chuck cover 70, so that deposition of the grinding residues contained in the grinding liquid can be suppressed.

Further, unlike an annular member having a pyramid shape, the conical annular member 71 can drain the grinding liquid radially, allowing the grinding liquid to be drained while being uniformly distributed in the rotation direction of the chuck 20. Therefore, an unbalanced distribution of the grinding liquid can be suppressed, so that the deposition of the grinding residues can be suppressed.

The chuck 20 includes a holding table 21 configured to hold the substrate W. The holding table 21 has a disk-shaped porous body 21a and a base 21b including a recess in which the porous body 21a is disposed. The recess is formed in a top surface of the base 21b, and the porous body 21a is embedded in the recess.

When a gas inside the porous body 21a is sucked so that a pressure of the porous body 21a becomes a negative pressure lower than an atmospheric pressure, the substrate W is attracted to the porous body 21a. Meanwhile, when the sucking of the gas is stopped so that the pressure of the porous body 21a is returned to the atmospheric pressure, the attraction of the substrate W is released.

The chuck 20 has a flange 23 provided at a lower edge of the holding table 21. The flange 23 is detachably attached to a rotary table 25 by a fastener such as bolts 24. The plurality of bolts 24 are arranged at a distance therebetween in a circumferential direction of the flange 23.

The annular member 71 has an opening 71a. The diameter of the opening 71a is larger than the diameter of the substrate W and smaller than the diameter of the flange 23 of the chuck 20. The bolts 24 can be hidden directly under the annular member 71, so it is possible to suppress the grinding liquid from colliding with the bolts 24. Therefore, scattering of the grinding liquid can be suppressed.

The chuck cover 70 has a cylindrical member 73 extending downwards from a lower edge of the annular member 71. Although the cylindrical member 73 is extended straightly downwards from the lower edge of the annular member 71 in the present exemplary embodiment, it may be extended diagonally downwards. A center line of the cylindrical member 73 coincides with the rotation center line R2 of the chuck 20. The cylindrical member 73 guides the grinding liquid dripping from the annular member 71 downwards.

The cylindrical member 73 is inserted through a hole 64 of the inclined member 61 of the table cover 60. The hole 64 guides the grinding liquid flowing down along the cylindrical member 73 to below the inclined member 61. As compared to a case where the cylindrical member 73 is disposed on the inclined member 61 because there is no hole 64, accumulation of the grinding liquid on the inclined member 61 can be suppressed, so that the deposition of the grinding residues can be suppressed.

As shown in FIG. 4, the grinding apparatus 1 has a stand 80 and a base cover 90. The stand 80 is a place, under the inclined member 61 of the table cover 60, on which the cylindrical member 73 of the chuck cover 70 is disposed. The base cover 90 receives the grinding liquid dripping from the hole 64 of the inclined member 61 from above the table 10 and below the table cover 60. The base cover 90 is fixed to the table 10 and rotated along with the table 10.

The stand 80 is provided on a top surface of the base cover 90 so as to be projected therefrom. The stand 80 supports the cylindrical member 73 of the chuck cover 70 from above the base cover 90. As compared to a case where the cylindrical member 73 is disposed on the top surface of the base cover 90, the length of the cylindrical member 73 can be shortened.

The chuck cover 70 further includes a plate-shaped member 74 horizontally provided at an outer periphery of the cylindrical member 73. A notch 65 through which the plate-shaped member 74 of the chuck cover 70 passes is formed at an opening edge of the hole 64 of the inclined member 61 of the table cover 60. The plate-shaped member 74 of the chuck cover 70 is formed at, for example, a lower end of the cylindrical member 73, and is disposed on the stand 80 and fixed thereto with a bolt 81 or the like in a removable manner. With the table cover 60 mounted, a tool can be inserted into the notch 65 to loosen or tighten the bolt 81, so that the chuck cover 70 can be separated or mounted.

The base cover 90 has a disk member 91 horizontally disposed above the table 10. The diameter of the disk member 91 is larger than the diameter of the table 10. The grinding liquid dropped on the disk member 91 is drained from a gap between the disk member 91 and the straight member 63 of the table cover 60.

The disk member 91 is provided with a plurality of openings 91a. These openings 91a are arranged at an equal distance therebetween around the rotation center line R1 of the table 10. A rotation shaft 26 configured to rotate the rotary table 25 is inserted through the opening 91a.

The rotation shaft 26 extends vertically downwards from a rotation center of the rotary table 25. An outer cylindrical member 27 extending downwards is provided at a periphery of the rotary table 25. Although the outer cylindrical member 27 is extended straightly downwards from the periphery of the rotary table 25 in the present exemplary embodiment, it may be extended obliquely downwards. Inside the outer cylindrical member 27, there is disposed an inner cylindrical member 93.

The inner cylindrical member 93 extends upwards from the opening edge of the opening 91a of the disk member 91. Although the inner cylindrical member 93 is extended straightly upwards from the opening edge of the opening 91a of the disk member 91 in the present exemplary embodiment, it may be extended obliquely upwards. A height of an upper end of the inner cylindrical member 93 is higher than a height of a lower end of the outer cylindrical member 27. A labyrinth which suppresses introduction of the grinding liquid can be formed by the inner cylindrical member 93 and the outer cylindrical member 27.

The plurality of openings 91a are arranged at the equal distance therebetween around the rotation center line R1 of the table 10 as stated above. The rotary partition walls 15 are disposed between the openings 91a neighboring in the rotation direction of the table 10. The rotary partition wall 15 is disposed on the disk member 91. The stand 80 is also provided on the disk member 91.

The base cover 90 has a cylindrical member 94 extending downwards from an edge of the disk member 91. Although the cylindrical member 94 is extended straightly downwards from the edge of the disk member 91 in the present exemplary embodiment, it may be extended obliquely downwards. A center line of the cylindrical member 94 coincides with the rotation center line R1 of the table 10. The cylindrical member 94 is disposed farther from the rotation center line R1 of the table 10 than the table 10, and allows the grinding liquid to fall outside the table 10. The cylindrical member 94 is positioned on an extension line of the straight member 63 of the table cover 60, and guides the grinding liquid dripping along the straight member 63 further downwards.

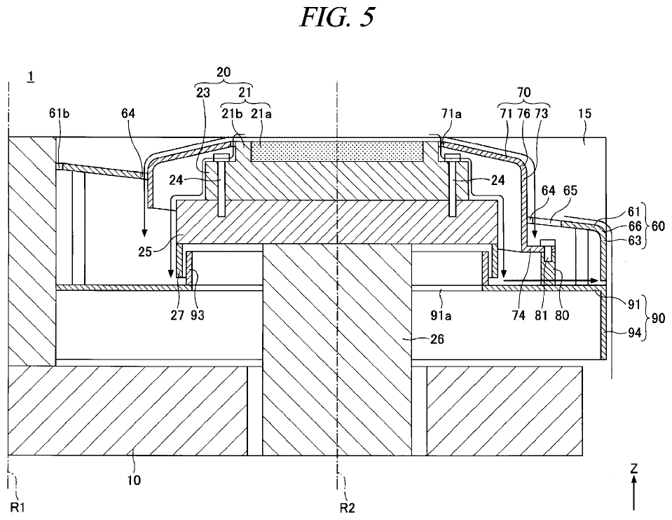

Now, with reference to FIG. 5, a table cover and a chuck cover according to a modification example will be described. Below, the description will be mainly focused on differences between the present modification example and the above-described exemplary embodiment.

The table cover 60 has a curved member 66 allowing a corner between the inclined member 61 and the straight member 63 to be rounded. The curved member 66 has a so-called R-chamfered shape. The curved member 66 enables the grinding liquid to be smoothly guided from the inclined member 61 to the straight member 63, so that the scattering of the grinding liquid can be suppressed.

Likewise, the chuck cover 70 has a curved member 76 allowing a corner between the annular member 71 and the cylindrical member 73 to be rounded. The curved member 76 has a so-called R-chamfered shape. The curved member 76 enables the grinding liquid to be smoothly guided from the annular member 71 to the cylindrical member 73, so that the scattering of the grinding liquid can be suppressed.

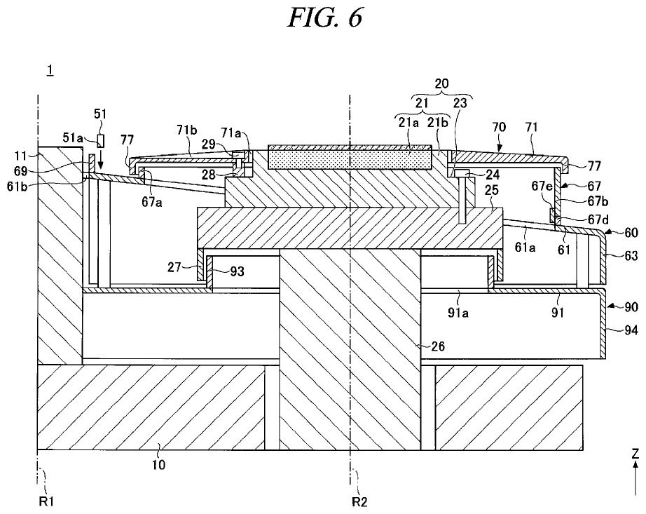

Next, with reference to FIG. 6, etc., the grinding apparatus 1 according to a second modification example will be explained. The content of the present modification example is also applicable to the above-described embodiment and the like.

As illustrated in FIG. 6, the grinding apparatus 1 includes the chuck cover 70 configured to be rotated along with the chuck 20. The chuck 20 includes the holding table 21 configured to hold the substrate W, and the flange 23 provided at the lower edge of the holding table 21. The holding table 21 has the porous body 21a and the base 21b. A recess is formed in the top surface of the holding table 21, and the disk-shaped porous body 21a is embedded in the recess.

When a gas inside the porous body 21a is sucked so that the pressure of the porous body 21a becomes a negative pressure lower than the atmospheric pressure, the substrate W is attracted to the porous body 21a. Meanwhile, when the sucking of the gas is stopped so that the pressure of the porous body 21a is returned to the atmospheric pressure, the attraction of the substrate W is released.

The chuck 20 is disposed on the rotary table 25, and is fixed to the rotary table 25 with a fastener. Although the fastener is not particularly limited, it may be, by way of example, the bolts 24. The plurality of bolts 24 are arranged at a distance therebetween in the circumferential direction of the flange 23 of the chuck 20. A shaft portion of the bolt 24 is screwed into a bolt hole of the rotary table 25 through a through hole of the flange 23. A head portion of the bolt 24 presses the flange 23 from above. By loosening or tightening the bolt 24, the chuck 20 can be replaced.

The chuck cover 70 includes an annular overhanging member 71. The annular overhanging member 71 is provided with, in the center thereof, an opening 71a into which the holding table 21 of the chuck 20 is inserted. A top surface of the overhanging member 71 is on a level with or lower than a top surface of the holding table 21 of the chuck 20. In addition, the top surface of the overhanging member 71 is disposed above the inclined member 61 of the table cover 60.

The top surface of the overhanging member 71 is inclined downwards as it goes away from the rotation center line R2 of the chuck 20. Further, the top surface of the overhanging member 71 may be horizontal. However, if the top surface of the overhanging member 71 is inclined, the grinding liquid can be drained obliquely downwards by gravity, so that the deposition of the grinding residues mixed with the grinding liquid can be suppressed. The top surface of the overhanging member 71 has, by way of non-limiting example, a conical shape.

The overhanging member 71 is disposed above the flange 23 of the chuck 20, and covers the bolt 24 serving as the fastener from above. The diameter of the opening 71a formed in the center of the overhanging member 71 is larger than the diameter of the holding table 21 and smaller than the diameter of the flange 23. The bolt 24 can be hidden directly below the overhanging member 71, and it is possible to suppress the grinding liquid from colliding with the bolt 24. Therefore, the scattering of the grinding liquid can be suppressed.

According to the present modification example, the chuck cover 70 is rotated along with the chuck 20. If the chuck 20 is rotated at the time of performing the grinding of the substrate W, the overhanging member 71 is rotated, and the grinding liquid adhering to the overhanging member 71 can be blown radially outwards by a centrifugal force. Therefore, the deposition of the grinding residues mixed with the grinding liquid can be suppressed, and the deposition of the grinding residues near the chuck 20 can be suppressed. As a result, it is possible to suppress the contamination of the operator or the work robot during the maintenance such as replacement of the chuck 20 or the grinding tool D. In addition, it is possible to suppress the accumulated grinding residues from being peeled off and adhering to the chuck 20 or the substrate W.

A spacer 28 is provided between the overhanging member 71 of the chuck cover 70 and the flange 23 of the chuck 20. The spacer 28 is plural in number, and the plurality of spacers 28 are provided at a distance therebetween in the circumferential direction of the flange 23. The overhanging member 71 is disposed on top of the plurality of spacers 28. Further, the spacer 28 may be integrated as one body with the overhanging member 71. In that case, the spacer 28 is disposed on the flange 23, and a shaft portion of the bolt 29 to be described later is screwed into a bolt hole of the flange 23.

The spacer 28 forms a gap between the overhanging member 71 and the flange 23. As compared to a case where there is no gap, the thickness of the overhanging member 71 can be made small, and the overhanging member 71 can be reduced in weight. Moreover, a space for accommodating a head portion of the bolt 24 can be secured between the overhanging member 71 and the flange 23.

The spacer 28 has a bolt hole on a top surface thereof. The shaft portion of the bolt 29 serving to fix the overhanging member 71 to the spacer 28 is screwed into the bolt hole. The head portion of the bolt 29 presses the overhanging member 71 from above. A groove 71b extending in a diametrical direction of the chuck 20 is formed on the top surface of the overhanging member 71. The groove 71b accommodates the head portion of the bolt 29 therein, and the head portion of the bolt 29 presses a bottom of the groove 71b from above.

While the top surface of the overhanging member 71 is inclined, a bottom surface of the overhanging member 71 is horizontal. If the bottom surface of the overhanging member 71 is horizontal, the overhanging member 71 can be stably disposed on the plurality of spacers 28. The number of the spacers 28 is desirably three or more.

The chuck cover 70 includes an outer cylindrical member 77 extending downwards from a periphery of the overhanging member 71. Although the outer cylindrical member 77 is extended straightly downwards in FIG. 6, it may be extended obliquely downwards. The outer cylindrical member 77 is extended below an upper end of an inner cylindrical member 67 of the table cover 60 to surround the inner cylindrical member 67. The inner cylindrical member 67 and the outer cylindrical member 77 form a labyrinth that suppresses the introduction of the grinding liquid.

A boundary between the overhanging member 71 and the outer cylindrical member 77 has, for example, a chamfered shape and a curved shape. If the boundary has an angled shape, a surface tension of liquid droplets may inhibit the liquid droplets from crossing the boundary. As a result, a ring-shaped liquid puddle may be easily formed. If the boundary between the overhanging member 71 and the outer cylindrical member 77 has the curved shape, on the other hand, the liquid droplets may easily cross the boundary, and the grinding liquid may be easily drained. Therefore, the grinding residues mixed with the grinding liquid can be suppressed from being stuck in a ring shape.

As illustrated in FIG. 6, the grinding apparatus 1 has the table cover 60 configured to be rotated together with the table 10. The table cover 60 has the inclined member 61 which is inclined downwards as it goes away from the rotation center line R1 of the table 10.

The inclined member 61 is disposed below the top surface of the holding table 21 of the chuck 20 and above the table 10. Unlike a horizontal flat member, the inclined member 61 can drain the grinding liquid obliquely downwards by gravity. Therefore, it is possible to suppress the accumulation of the grinding residues mixed with the grinding liquid.

The inclined member 61 has a conical shape with a constant height in the circumferential direction of the table 10, for example. When the inclined member 61 has the conical shape, the grinding liquid can be radially drained as indicated by the arrows in FIG. 3, so that the deposition of the grinding residues around the chuck 20 can be suppressed.

The inclined member 61 is provided with, between a top portion and a distal end thereof, the opening 61a into which the rotary table 25 is inserted. The opening 61a is formed for each rotary table 25, and is formed in multiple numbers at a distance therebetween around the rotation center line R1 of the table 10. The plurality of openings 61a are formed at, for example, an equal distance therebetween.

The table cover 60 includes the inner cylindrical member 67 that extends upwards from an opening edge of the opening 61a of the inclined member 61. Although the inner cylindrical member 67 is extended straightly upwards in FIG. 6, it may be extended obliquely upwards. An upper edge of the inner cylindrical member 67 is horizontal over the entire circumferential direction thereof. The inner cylindrical member 67 suppresses the grinding liquid from entering the opening 61a.

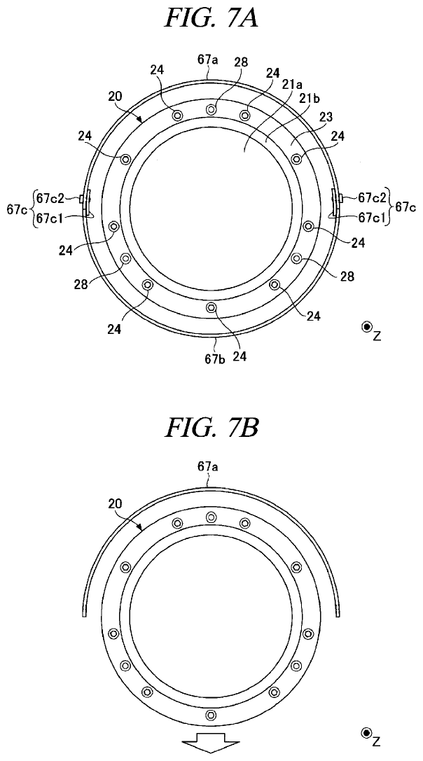

As shown to FIG. 7A, the inner cylindrical member 67 includes a first arc-shaped cylindrical member 67a, a second arc-shaped cylindrical member 67b, and a connecting member 67c. The first arc-shaped cylindrical member 67a is fixed to the inclined member 61. The second arc-shaped cylindrical member 67b is detachably connected to the first arc-shaped cylindrical member 67a. The connecting member 67c connects the first arc-shaped cylindrical member 67a and the second arc-shaped cylindrical member 67b annularly.

The connecting member 67c includes, by way of example, a connecting plate 67c1 and a bolt 67c2. The connecting plate 67c1 is fixed to, for example, an inner peripheral surface of the second arc-shaped cylindrical member 67b and is extended up to an inner peripheral surface of the first arc-shaped cylindrical member 67a. A shaft portion of the bolt 67c2 is screwed into a bolt hole of the connecting plate 67c1 through a through hole of the first arc-shaped cylindrical member 67a. A head portion of the bolt 67c2 presses the first arc-shaped cylindrical member 67a from a radially outside thereof.

In addition, the structure of the connecting member 67c is not particularly limited. For example, the connecting plate 67c1 may be fixed to the inner peripheral surface of the first arc-shaped cylindrical member 67a, and may be extended up to the inner peripheral surface of the second arc-shaped cylindrical member 67b. In this case, the shaft portion of the bolt 67c2 is screwed into the bolt hole of the connecting plate 67c1 through a through hole of the second arc-shaped cylindrical member 67b. The head portion of the bolt 67c2 presses the second arc-shaped cylindrical member 67b from a radially outside thereof.

Either way, by loosening or tightening the bolt 67c2, the second arc-shaped cylindrical member 67b can be removed or installed. As can be clearly seen from FIG. 7B, by separating the second arc-shaped cylindrical member 67b, the chuck 20 can be easily replaced.

As depicted in FIG. 6, the second arc-shaped cylindrical member 67b is disposed at an outer side than the first arc-shaped cylindrical member 67a in the diametrical direction of the table 10. At least a part of a lower edge of the second arc-shaped cylindrical member 67b is disposed below the top surface of the rotary table 25.

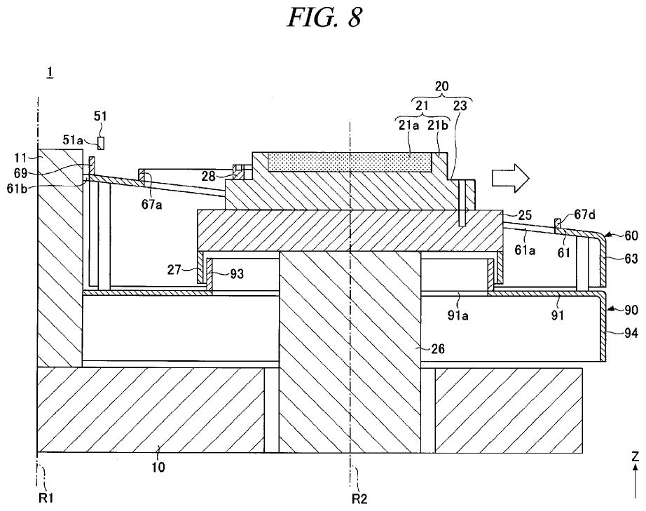

As a result, if the second arc-shaped cylindrical member 67b is removed, the chuck 20 mounted on the top surface of the rotary table 25 can be pulled out sideways, as shown in FIG. 8. This is advantageous when the chuck 20 cannot be removed upwards as the chuck 20 and the rotary table 25 have strong adhesion.

As shown in FIG. 6, the inner cylindrical member 67 may further include a third arc-shaped cylindrical member 67d on which the second arc-shaped cylindrical member 67b is mounted. The third arc-shaped cylindrical member 67d may be fixed to the inclined member 61, and may be integrated as one body with the first arc-shaped cylindrical member 67a.

The inner cylindrical member 67 may further include an alignment member 67e configured to align the second arc-shaped cylindrical member 67b and the third arc-shaped cylindrical member 67d. The alignment member 67e is fixed to, for example, the inner peripheral surface of the second arc-shaped cylindrical member 67b, and is inserted into the third arc-shaped cylindrical member 67d. As the alignment member 67e comes into contact with an inner peripheral surface of the third arc-shaped cylindrical member 67d, the second arc-shaped cylindrical member 67b and the third arc-shaped cylindrical member 67d are aligned.

The table cover 60 has the cylindrical member 63 extending downwards from the lower edge of the inclined member 61. Although the cylindrical member 63 is extended straightly downwards in FIG. 6, it may be extended obliquely downwards. The cylindrical member 63 allows the grinding liquid to fall outside the table 10. The outer diameter of the cylindrical member 63 is larger than the diameter of the table 10.

A boundary between the inclined member 61 and the cylindrical member 63 has, for example, a chamfered shape and a curved shape. As compared to a case where the boundary is of an angled shape, liquid droplets may easily cross the boundary, and the grinding liquid can be easily drained. Therefore, it is possible to suppress the grinding residues mixed with the grinding liquid to be stuck in a ring shape.

The inclined member 61 is provided with, at the top portion thereof, the opening 61b through which a fixed shaft 11 passes. The table cover 60 has a central cylindrical member 69 extending upwards from the opening edge of the opening 61b of the inclined member 61. Although the central cylindrical member 69 is extended straightly upwards in FIG. 6, it may be extended obliquely upwards. The central cylindrical member 69 suppresses the grinding liquid from entering the opening 61b.

The table cover 60 is divided into a plurality of division covers in the circumferential direction of the table 10. The number of the division covers is the same as the number of the chucks 20. The rotary partition walls 15 are disposed between the division covers neighboring in the circumferential direction.

The plurality of division covers are individually provided to the table 10 in the removable manner. For maintenance, each division cover can be separated individually. Since it is not necessary to remove the whole table cover 60 at once, the workability can be improved.

The grinding apparatus 1 includes the base cover 90. The base cover 90 has the horizontal disk member 91. The disk member 91 is disposed above the table 10 under the table cover 60 to be concentric with the table 10. The diameter of the disk member 91 is larger than the diameter of the table 10.

The disk member 91 is provided with, around the rotation center line R1 of the table 10, the opening 91a through which the rotation shaft 26 of the chuck 20 passes. The opening 91a is plural in number, and these openings 91a are arranged at an equal distance therebetween around the rotation center line R1 of the table 10.

The base cover 90 includes the inner cylindrical member 93 extending upwards from the opening edge of the opening 91a. Although the inner cylindrical member 93 is extended straightly upwards in FIG. 6, it may be extended diagonally upwards. The rotation shaft 26 is inserted through the inner cylindrical member 93.

The rotation shaft 26 is extended vertically downwards from the rotation center of the rotary table 25. The outer cylindrical member 27 extending downwards is provided at the periphery of the rotary table 25. Although the outer cylindrical member 27 is extended straightly downwards in FIG. 6, it may be extended diagonally downwards.

The outer cylindrical member 27 is extended below the upper end of the inner cylindrical member 93 of the base cover 90 to surround the inner cylindrical member 93. A labyrinth that suppresses the introduction of the grinding liquid can be formed by the inner cylindrical member 93 and the outer cylindrical member 27.

The openings 91a are arranged at the equal distance therebetween around the rotational center line R1 of the table 10 as mentioned above. The rotary partition walls 15 are disposed between the openings 91a neighboring in the circumferential direction of the table 10. The rotary partition walls 15 are provided on the disk member 91.

The base cover 90 has the cylindrical member 94 extending downwards from the periphery of the disk member 91. Although the cylindrical member 94 is extended straightly downwards in FIG. 6, it may be extended diagonally downward.

A boundary between the disk member 91 and the cylindrical member 94 has, for example, a chamfered shape and a curved shape. As compared to a case where the boundary has an angled shape, it is easy for liquid droplets to cross the boundary, so that the grinding liquid can be easily drained. Thus, it is possible to suppress the grinding residues mixed with the grinding liquid to be stuck in a ring shape.

As illustrated in FIG. 6, the grinding apparatus 1 is equipped with a nozzle 51 configured to supply a cleaning liquid to the inclined member 61 from between the top portion of the inclined member 61 of the table cover 60 and the chuck 20. The nozzle 51 supplies the cleaning liquid to the inclined member 61 from above. The nozzle 51 may be provided at the central cylindrical member 69. The cleaning liquid is, for example, pure water. After the cleaning liquid is supplied to the inclined member 61, it flows obliquely downwards and fall down due to gravity. With the cleaning liquid, a wide range of the inclined member 61 can be cleaned, so that the deposition of the grinding residues around the chuck 20 can be suppressed. The nozzle 51 may supply the cleaning liquid to the inclined member 61 from a position allowing the cleaning liquid to reach the top portion of the inclined member 61. The entire inclined member 61 ranging from the top portion to the distal end thereof can be cleaned.

The nozzle 51 discharges the cleaning liquid during the grinding of the substrate W, for example, to thereby wash off the grinding liquid and the grinding residues adhering to the inclined member 61. The nozzle 51 is provided not only in the first grinding chamber B1 but also in the second grinding chamber B2 and the third grinding chamber B3. The nozzle 51 may be provided in the carry-in/out chamber B0 as well. The nozzle 51 may discharge the cleaning liquid when the grinding of the substrate W is not performed.

The inclined member 61 of the table cover 60 is provided with, at the top portion thereof, the opening 61b through which the fixed shaft 11 passes. The central cylindrical member 69 extends upwards from the opening edge of the opening 61b, and the nozzle 51 is disposed at the radially outside of the central cylindrical member 69. It is possible to suppress the cleaning liquid from reaching the inside of the central cylindrical member 69.

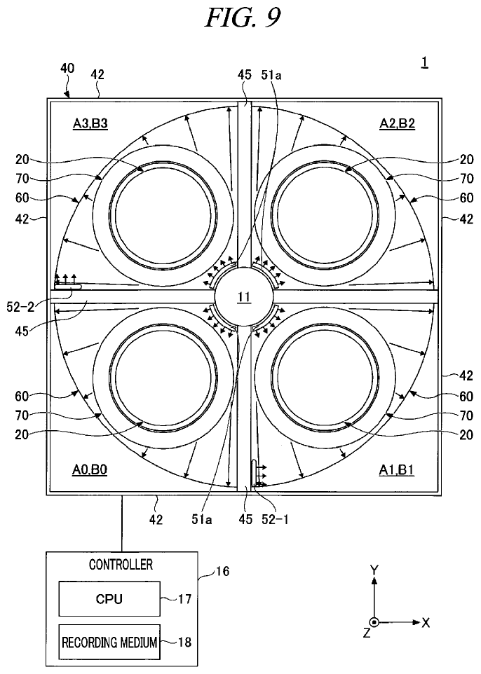

As shown in FIG. 9, supply openings 51a of the nozzles 51 are provided at a distance therebetween in the circumferential direction of the table cover 60 (rotation direction of the table cover 60). A plurality of supply openings 51a may be provided in one room (for example, first grinding chamber B1). Due to the presence of the plurality of supply openings 51a, the wide range of the inclined member 61 of the table cover 60 in the circumferential direction can be cleaned at one time. In addition, the supply opening 51a of the nozzle 51 is an arc-shaped slit formed along the circumferential direction of the table cover 60. With this configuration, the cleaning liquid can be supplied at a position close to the top portion of the inclined member 61 of the table cover 60. Further, the supply opening 51a of the nozzle 51 may be straight line-shaped slit or a circular hole.

However, at the distal end of the inclined member 61, the surface tension of the liquid droplet inhibit the liquid droplets from flowing over the distal end. As a result, a ring-shaped liquid puddle is likely to be formed, resulting in adhesion of a ring-shaped contaminant.

To solve this problem, the grinding apparatus 1 is equipped with nozzles 52-1 and 52-2 configured to supply a cleaning liquid to the distal end of the inclined member 61 of the table cover 60 from above. The cleaning liquid is, for example, pure water. The cleaning liquid washes away the grinding liquid contaminated with the grinding residues, thus suppressing the adhesion of the ring-shaped contaminant.

In the first grinding chamber B1, the nozzle 52-1 is located in the vicinity of a boundary between the first grinding chamber B1 and the carry-in/out chamber B0. The vicinity of the boundary means a range within 50 mm from the fixed partition wall 45 which is the boundary. At least a part of a discharge opening of the nozzle 52-1 needs to be located within the range.

Meanwhile, in the third grinding chamber B3, the nozzle 52-2 is located in the vicinity of a boundary between the third grinding chamber B3 and the carry-in/out chamber B0. The vicinity of the boundary means a range within 50 mm from the fixed partition wall 45 which is the boundary. At least a part of a discharge opening of the nozzle 52-2 needs to be located within the range.

While the table 10 is being rotated in the clockwise direction when viewed from above, a controller 16 is configured to supply the cleaning liquid to the distal end of the inclined member 61 of the table cover 60 from the nozzle 52-1 disposed in the first grinding chamber B1. The distal end of the inclined member 61 can be cleaned just before it is moved from the first grinding chamber B1 to the carry-in/out chamber B0, so that it is possible to suppress the contaminant from being carried into the carry-in/out chamber B0.

Meanwhile, while the table 10 is being rotated in the counterclockwise direction when viewed from above, the controller 16 supplies the cleaning liquid to the distal end of the inclined member 61 of the table cover 60 from the nozzle 52-2 disposed in the third grinding chamber B3. The distal end of the inclined member 61 can be cleaned just before it is moved from the third grinding chamber B3 to the carry-in/out chamber B0, so that it is possible to suppress t contaminant from being carried into the carry-in/out chamber B0.

The grinding apparatus 1 is equipped with the controller 16. The controller 16 is, for example, a computer, and includes a CPU (Central Processing Unit) 17 and a recording medium 18 such as a memory. The recording medium 18 stores therein a program for controlling various kinds of processings performed in the grinding apparatus 1. The controller 16 controls an operation of the grinding apparatus 1 by causing the CPU 17 to execute the program stored in the recording medium 18.

So far, the grinding apparatus according to the present disclosure has been described. However, the present disclosure is not limited to the above-described exemplary embodiment and the like. Various changes, modifications, substitutions, additions, deletions and combinations may be made within the scope of the claims, which are all incorporated within a technical scope of the present disclosure.

For example, although the technique of the present disclosure is applied to the grinding apparatus 1 in the above-described exemplary embodiment, it can also be applied to a cutting apparatus, etc. The grinding includes polishing. The technique of the present disclosure is applicable to any removing apparatus configured to remove a part of the substrate W, as processing residues are produced by the process of removing a part of the substrate W. Further, in the process of removing a part of the substrate W, a processing liquid is supplied to the substrate W in order to reduce frictional resistance between the substrate W and a processing tool.

This application claims priority to Japanese Patent Application No. 2020-052488 field on Mar. 24, 2020 and Japanese Patent Application No. 2020-161269 filed on Sep. 25, 2020, which applications are hereby incorporated by reference in their entirety.

### EXPLANATION OF CODES

1: Grinding apparatus (Removing apparatus)
10: Table
20: Chuck
50: Nozzle
60: Table cover
61: Inclined member

1. A removing apparatus, comprising:
a horizontal table configured to be rotated around a vertical rotation center line;
multiple chucks disposed at a distance therebetween around the rotation center line of the table;
a nozzle configured to supply a processing liquid to a substrate held by the chuck; and
a table cover configured to receive the processing liquid from above the table,
wherein the table cover has an inclined member of a conical shape having a decreasing height as the inclined member goes away from the rotation center line of the table while having a constant height in a rotation direction of the table.

2. The removing apparatus of claim 1,
wherein the table cover includes a straight member extending downwards from a lower edge of the inclined member, and a curved member allowing a corner between the inclined member and the straight member to be rounded.

3. The removing apparatus of claim 1,
wherein the table cover is divided into multiple division covers between the chucks neighboring in the rotation direction of the table, and
the multiple division covers are individually provided to the table in a removable manner.

4. The removing apparatus of claim 1, further comprising:
a chuck cover protruding upwards from the inclined member of the table cover, and configured to receive the processing liquid from around the chuck.

5. The removing apparatus of claim 4,
wherein the chuck cover has an annular member of a conical shape having a decreasing height as the annular member goes away from a rotation center line of the chuck while having a constant height in a rotation direction of the chuck.

6. The removing apparatus of claim 5,
wherein the chuck cover includes a cylindrical member extending downwards from a lower edge of the annular member, and a curved member allowing a corner between the annular member and the cylindrical member to be rounded.

7. The removing apparatus of claim 5,
wherein the chuck cover includes a cylindrical member extending downwards from a lower edge of the annular member, and
the inclined member of the table cover is provided with a hole through which the cylindrical member is inserted.

8. The removing apparatus of claim 5,
wherein the chuck cover includes a cylindrical member extending downwards from a lower edge of the annular member, and a curved member allowing a corner between the annular member and the cylindrical member to be rounded, and
the inclined member of the table cover is provided with a hole through which the cylindrical member is inserted.

9. The removing apparatus of claim 7, further comprising:
a base cover configured to receive the processing liquid from above the table and below the table cover; and
a stand which is disposed below the inclined member of the table cover and on which the cylindrical member of the chuck cover is disposed,
wherein the stand is protruded on a top surface of the base cover.

10. The removing apparatus of claim 9,
wherein the chuck cover further includes a plate-shaped member horizontally provided at an outer periphery of the cylindrical member,
a notch through which the plate-shaped member of the chuck cover passes is formed at an opening edge of the hole of the inclined member of the table cover, and
the plate-shaped member of the chuck cover is disposed on the stand and mounted to the stand in a removable manner.

11. The removing apparatus of claim 1, further comprising:
a base cover configured to receive the processing liquid from above the table and below the table cover;
a rotary table on which the chuck is mounted;
a rotation shaft extending vertically downwards from a rotation center of the rotary table; and
an outer cylindrical member extending downwards from a periphery of the rotary table,
wherein the base cover includes a disk member horizontally disposed above the table, an opening through which the rotation shaft is inserted, and an inner cylindrical member extending upwards from an edge of the opening, and
the inner cylindrical member is disposed inside the outer cylindrical member.

12. The removing apparatus of claim 7, further comprising:
a base cover configured to receive the processing liquid from above the table and below the table cover;
a rotary table on which the chuck is mounted;
a rotation shaft extending vertically downwards from a rotation center of the rotary table;
an outer cylindrical member extending downwards from a periphery of the rotary table; and
a stand which is disposed below the inclined member of the table cover and on which the cylindrical member of the chuck cover is disposed,
wherein the base cover includes a disk member horizontally disposed above the table, an opening through which the rotation shaft is inserted, and an inner cylindrical member extending upwards from an edge of the opening,
the inner cylindrical member is disposed inside the outer cylindrical member, and
the stand is provided on a top surface of the base cover to be projected therefrom.

13. The removing apparatus of claim 1,
wherein the chuck includes a holding table configured to hold the substrate, and a flange provided at a lower edge of the holding table,
wherein the removing apparatus comprises:
a rotary table on which the chuck is mounted;
a fastener configured to fasten the flange of the chuck to the rotary table; and
a chuck cover configured to be rotated along with the chuck, and
wherein the chuck cover includes an annular overhanging member having, in a center thereof, an opening into which the holding table is inserted, and
the overhanging member is disposed above the flange, and covers the fastener from above.

14. The removing apparatus of claim 13, further comprising:
a spacer configured to form a gap between the overhanging member of the chuck cover and the flange of the chuck.

15. The removing apparatus of claim 13,
wherein the rotary table includes multiple rotary tables, and the table rotatably supports the multiple chucks with the multiple rotary tables therebetween, and the table is rotated about the rotation center line different from the rotation center line of the chuck,
the inclined member of the table cover is provided with, between a top portion and a distal end thereof, an opening into which the rotary table is inserted,
the table cover includes an inner cylindrical member extending upwards from an edge of the opening, and
the chuck cover includes an outer cylindrical member extending below an upper end of the inner cylindrical member from a periphery of the overhanging member to surround the inner cylindrical member.

16. The removing apparatus of claim 15,
wherein the inner cylindrical member of the table cover includes a first arc-shaped cylindrical member fixed to the inclined member of the table cover, a second arc-shaped cylindrical member connected to the first arc-shaped cylindrical member in a removable manner, and a connecting member connecting the first arc-shaped cylindrical member and the second arc-shaped cylindrical member.

17. The removing apparatus of claim 16,
wherein the second arc-shaped cylindrical member is disposed at an outer side than the first arc-shaped cylindrical member in a diametrical direction of the table, and
at least a part of a lower edge of the second arc-shaped cylindrical member is disposed below a top surface of the rotary table.

18. The removing apparatus of claim 1, further comprising:
a second nozzle configured to supply a cleaning liquid to a distal end of the inclined member of the table cover from above.

19. The removing apparatus of claim 18, further comprising:
a housing accommodating the multiple chucks inside, and a fixed partition wall that divides an inside of the housing into multiple rooms around the rotation center line of the table,
wherein the multiple rooms include a grinding chamber in which grinding of the substrate is performed, and a carry-in/out chamber in which a carry-in/out of the substrate is performed, and
the second nozzle is located in the grinding chamber near a boundary between the grinding chamber and the carry-in/out chamber.

20. The removing apparatus of claim 1, further comprising:
a nozzle configured to supply a cleaning liquid to the inclined member from between a top portion of the inclined member of the table cover and the chuck.
